(19) United States
(12) Patent Application Publication
(10) Pub. No.: US 2026/0156822 A1
(43) Pub. Date: Jun. 4, 2026

(54) THREE-DIMENSIONAL MEMORY DEVICES AND FABRICATING METHODS THEREOF

(71) Applicant: Yangtze Memory Technologies Co., Ltd., Wuhan (CN)

(72) Inventors: Wei Yuan, Wuhan (CN); Kun Zhang, Wuhan (CN); Yuhui Han, Wuhan (CN); Xiaojing Gu, Wuhan (CN)

(73) Assignee: Yangtze Memory Technologies Co., Ltd., Wuhan (CN)

(21) Appl. No.: 19/173,969

(22) Filed: Apr. 9, 2025

(30) Foreign Application Priority Data
Dec. 4, 2024 (CN) 202411777693.5

(51) Int. Cl. H10B 43/27; G11C 5/06; H10B 41/10; H10B 41/27; H10B 43/10

(52) U.S. Cl. CPC H10B 43/27; G11C 5/063; H10B 41/10; H10B 41/27; H10B 43/10

(57) ABSTRACT

Aspects of the disclosure provide a 3D device. The 3D device can include a first stack of alternating conductive layers and dielectric layers, a first dielectric layer that is formed over the first stack, and a first slit structure extending through the first stack and the first dielectric layer. The first slit structure is disposed adjacent to an array region. The 3D device can further include channel structures that are formed in the array region and extend through the first stack and the first dielectric layer. The first dielectric layer in the array region can include a first portion and a second portion. The first region is closer to the first slit structure than the second portion, and the second portion has a higher dopant concentration than the first portion.

### RELATED APPLICATIONS

This present application claims priority to Chinese application No. 202411777693.5, filed on Dec. 4, 2024, which is incorporated herein by reference in its entirety.

### TECHNICAL FIELD

The present disclosure relates to three-dimensional (3D) memory devices and fabrication methods thereof.

### BACKGROUND

Planar semiconductor memory devices are scaled to smaller sizes by improving process technology, circuit design, programming algorithm, and fabrication process. However, as feature sizes of the semi-conductor devices approach a lower limit, planar process and fabrication techniques become challenging and costly. A 3D semiconductor device architecture can address the density limitation in some planar semiconductor memory devices.

A semiconductor memory device can be formed by stacking semiconductor wafers or dies and interconnecting them vertically so that the resulting structure acts as a single device to achieve performance improvements at reduced power and a smaller footprint than conventional planar processes. Among the various techniques for stacking semi-conductor substrates, bonding, such as hybrid bonding, is recognized as one of the promising techniques because of its capability of forming high-density interconnects.

### SUMMARY

Aspects of the disclosure provide a 3D device. The 3D device can include a first stack of alternating conductive layers and dielectric layers, a first dielectric layer that is formed over the first stack, and a first slit structure extending through the first stack and the first dielectric layer. The first slit structure is disposed adjacent to an array region. The 3D device can further include channel structures that are formed in the array region and extend through the first stack and the first dielectric layer. The first dielectric layer in the array region can include a first portion and a second portion. The first portion is closer to the first slit structure than the second portion, and the second portion has a higher dopant concentration than the first portion.

In an example, the 3D memory device can further include a second slit structure and a separation structure that extend through the first stack and the first dielectric layer. The separation structure is disposed between the first slit structure and the second slit structure.

In an example, the first portion and the second portion of the first dielectric layer are separated by a boundary within the first dielectric layer. Dopant concentration of the first dielectric layer has a transition at the boundary from a higher concentration to a lower concentration. For example, the boundary in the first dielectric layer can extend substantially in parallel to an extending direction of the first slit structure.

In an example, the channel structures can each have a plug structure crossing the first dielectric layer, and the plug structures and the first dielectric layer in the second portion include a same type of doping element.

In an example, in a section crossing the first slit structure of the 3D memory device, a border between the first slit structure and the array region can have a wavy shape.

In an example, the 3D memory device can further include a second stack of dielectric layers, the second stack being adjacent to the first stack, and a connecting structure partially extending through the second stack and connecting with one of the conductive layers.

Aspects of the disclosure provide a 3D memory device. The 3D memory device can include a first stack of alternating conductive layers and dielectric layers, a first dielectric layer that is formed over the first stack, a first slit structure extending through the first stack and the first dielectric layer, the first slit structure being disposed adjacent to an array region, and channel structures that are formed in the array region and extend through the first stack and the first dielectric layer. The first dielectric layer in the array region can include a first portion and a second portion, the first portion being closer to the first slit structure than the second portion, the first portion and the second portion of the first dielectric layer being separated by a boundary within the first dielectric layer, dopant concentration of the first dielectric layer having a transition at the boundary from a higher concentration to a lower concentration.

Aspects of the disclosure provide a method for fabricating a 3D memory device. The method can include forming a semiconductor structure that include a stack of alternating sacrificial layers and dielectric layers, a first dielectric layer that is formed over the stack, channel structures extending through the stack and the first dielectric layer, the channel structures each having a plug structure at an end of the respective channel structure, and gate-line-slit (GLS) hole structures extending through the stack and into the first dielectric layer and arranged in a row. The method can further include forming a protection layer partially covering the first dielectric layer and doping the plug structures of the channel structures. The protection layer is positioned over the row of the GLS hole structures and a region of the first dielectric layer where the channel structures are located remains exposed.

In an example, the protection layer can be a photo resist layer.

In an example, the GLS hole structures include a first sequence of first GLS hole structures neighboring each other and a second sequence of second GLS hole structures neighboring each other in the row of the GLS hole structures, and the method can further include removing the protection layer, forming a second dielectric layer on top of the semiconductor structure covering the plug structures of the channel structures, performing an etch process to expose the first sequence of first GLS hole structures from a top of the semiconductor structure, removing a first sacrificial material from within the first sequence of first GLS hole structures to form a sequence of first GLS openings extending through the stack and the first dielectric layer, and performing an etch process to enlarge the first sequence of first GLS openings, wherein the enlarged sequence of first GLS openings merge with each other to form a first slit.

In an example, the method can further include filling the first slit with a second sacrificial material, performing an etch process to expose the sequence of second GLS hole structures from the top of the semiconductor structure, removing the first sacrificial material from within the sequence of second GLS hole structures to form a sequence of second GLS openings extending through the stack and the first dielectric layer, performing an etch process to enlarge the sequence of second GLS openings, and filling the separation slit with a first filling material. The enlarged sequence of second GLS openings merge with each other to form a separation slit.

In an example, the first filling material can be an insulation material.

In an example, the method can further include performing an etch process to remove the second sacrificial material from the first slit, replacing the sacrificial layers with word line layers through the first slit, and filling the first slit with a second filling material.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a block diagram of an example system 100 having a memory device, according to some aspects of the present disclosure.

FIG. 2A illustrates a diagram of an example memory card having a memory device, according to some aspects of the present disclosure.

FIG. 2B illustrates a diagram of an example solid-state drive (SSD) having a memory device, according to some aspects of the present disclosure

FIGS. 3-10 illustrate a fabrication process for forming a memory device.

FIG. 11 illustrates a flowchart of a fabrication process 1100 of forming a semiconductor device 1200 according to embodiments of the present disclosure.

FIGS. 12-25 illustrate a fabrication process for forming the semiconductor device 1200 according to aspects of the present disclosure.

FIG. 26 illustrates two semiconductor memory device architectures 2600A and 2600B where the fabrication methods disclosed herein are applied according to some implementations of the present disclosure.

FIG. 27 illustrates a top view and a cross-section view of a block 2700 of a semiconductor device having word line connecting structures, according to some aspects of the present disclosure.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for the existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

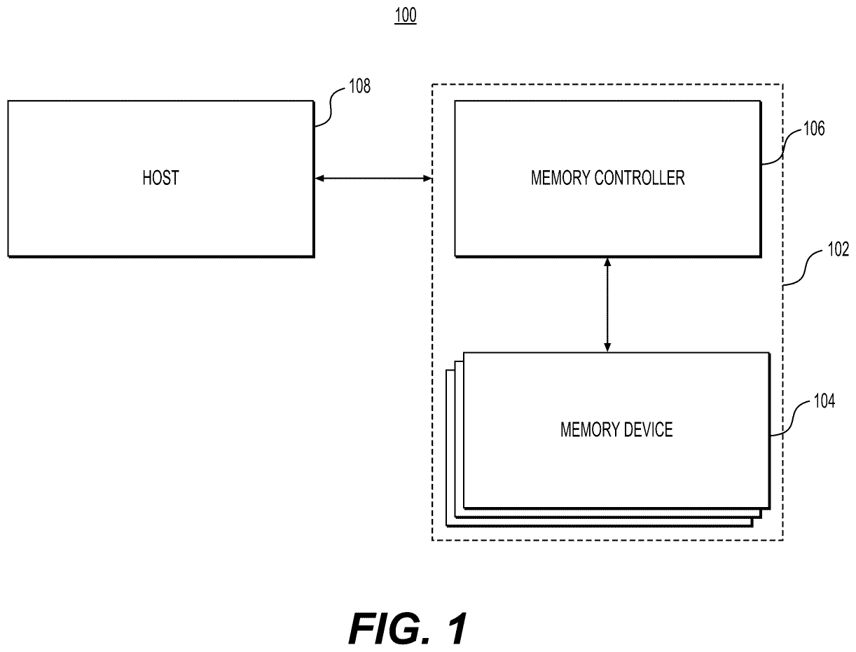

FIG. 1 illustrates a block diagram of an example system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an augmented reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data to or from memory devices 104.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, formatting memory device 104. Consistent with some aspects of the present disclosure, memory controller 106 is configured to perform mapping table rebuilding after an abnormal power off recovery, as described below in detail.

Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

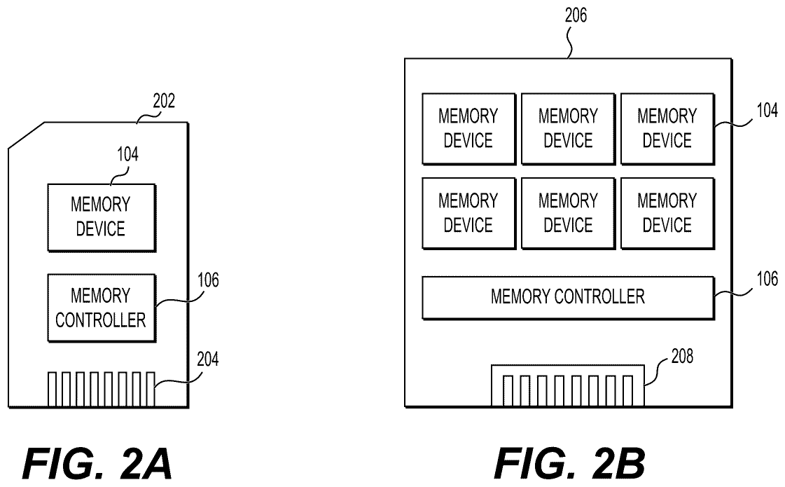

Memory controller 106 and one or more memory devices 104 can be integrated into various types of storage devices, for example, be included in the same package, such as a universal Flash storage (UFS) package or an eMMC package. That is, memory system 102 can be implemented and packaged into different types of end electronic products. In one example as illustrated in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling memory card 202 with a host (e.g., host 108 in FIG. 1). In another example as illustrated in FIG. 2B, memory controller 106 and multiple memory devices 104 may be integrated into an SSD 206. SSD 206 can further include an SSD connector 208 coupling SSD 206 with a host (e.g., host 108 in FIG. 1). In some implementations, the storage capacity and/or the operation speed of SSD 206 is greater than those of memory card 202.

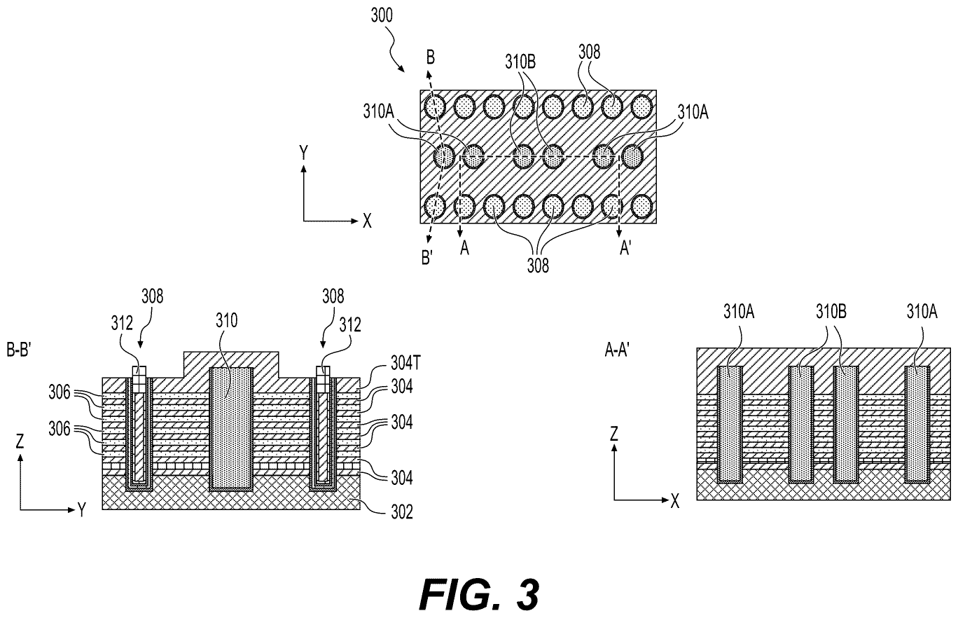

FIGS. 3-10 illustrate an example of fabrication process for forming a semiconductor device 300. Each figure includes a top view of the semiconductor device 300 at various steps of the fabrication process. Each figure also includes a cross-section view of the semiconductor device 300 along the AA′ cut line and a cross-section view of the semiconductor device 300 along the BB′ cut line.

As shown in FIG. 3, a stack structure including a plurality of dielectric layers 304 and a plurality of sacrificial layers 306 is formed on substrate 302. Dielectric layers 304 and sacrificial layers 306 are alternatingly arranged on substrate 302. Dielectric layers 304 and sacrificial layers 306 may extend along the x-direction and the y-direction. Channel structures 308 and gate-line-slit (GLS) hole structures 310A/310B (labeled as 310 in the AA′ cross-section view) are formed in the stack structure along the z-direction. A first sequence of GLS hole structures 310A can have multiple GLS hole structures 310A along the x direction. A second sequence of GLS hole structures 310B can have one or more GLS hole structures 310B along the x direction. The second sequence of GLS hole structures 310B can be disposed in between GLS hole structures 310A in the first sequence along the x direction. The channel structures 308 each can have a plug structure 312 at an end of the respective channel structure 308. As shown in the cross-section view along the BB′ cut line, the plug structures 312 are exposed while the GLS hole structures 310 are covered by the topmost dielectric layer 304T.

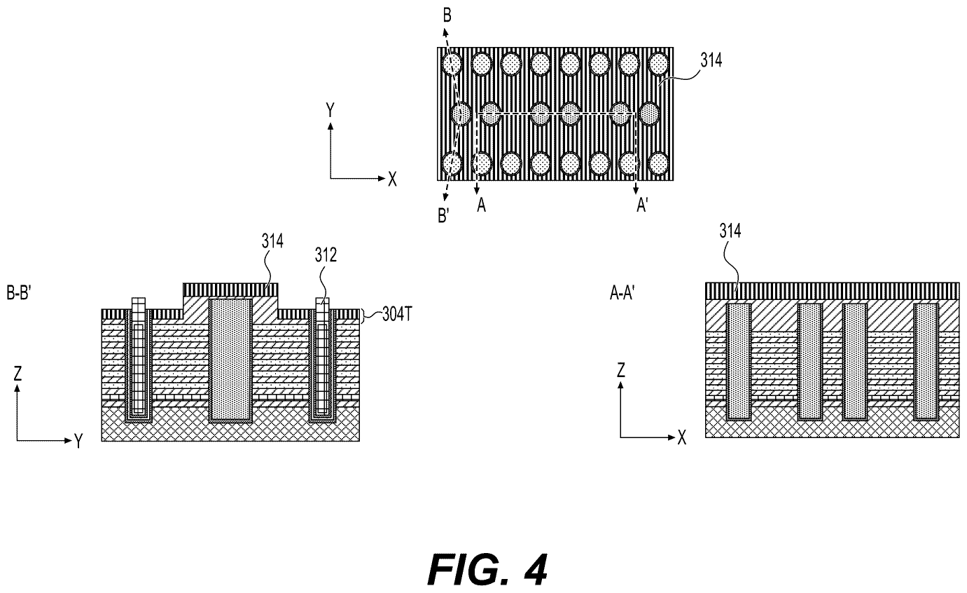

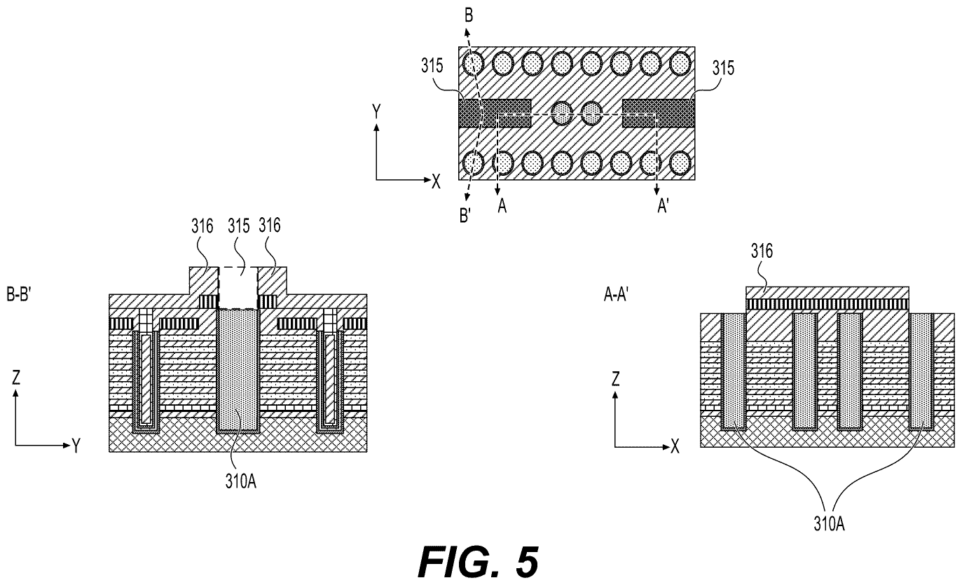

As shown in FIG. 4, doped region 314 is formed in the topmost dielectric layer 304T during a doping process (for example, ion implantation) for doping the plug structure 312. As shown in FIG. 5, a trench 315 is formed on the stack structure to expose the first sequence of GLS hole structures 310A. For example, a dielectric layer 316 is disposed on the stack structure. A photoresist layer (not shown) is formed over the dielectric layer 316 and patterned. An etch process is subsequently performed to expose the first sequence of GLS hole structure 310A.

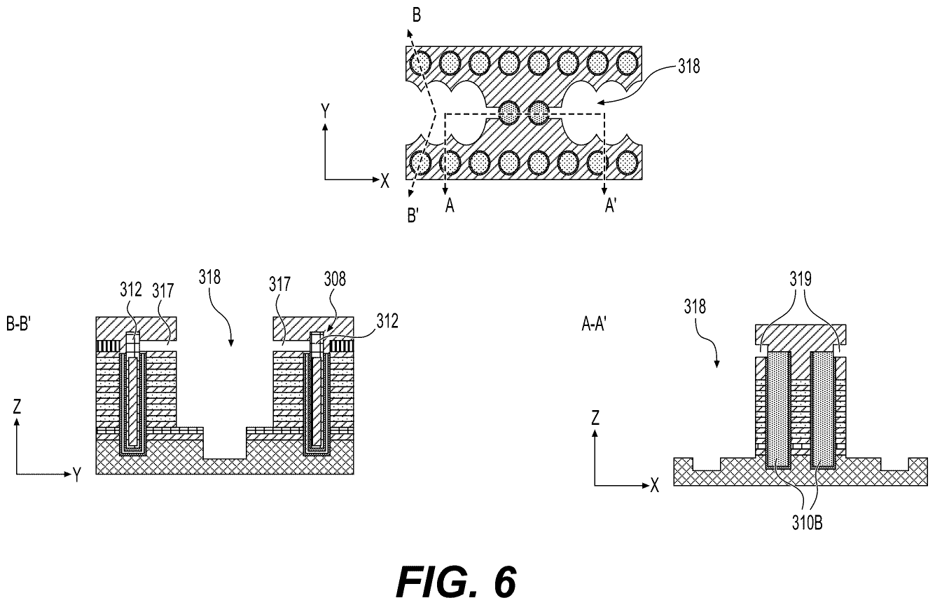

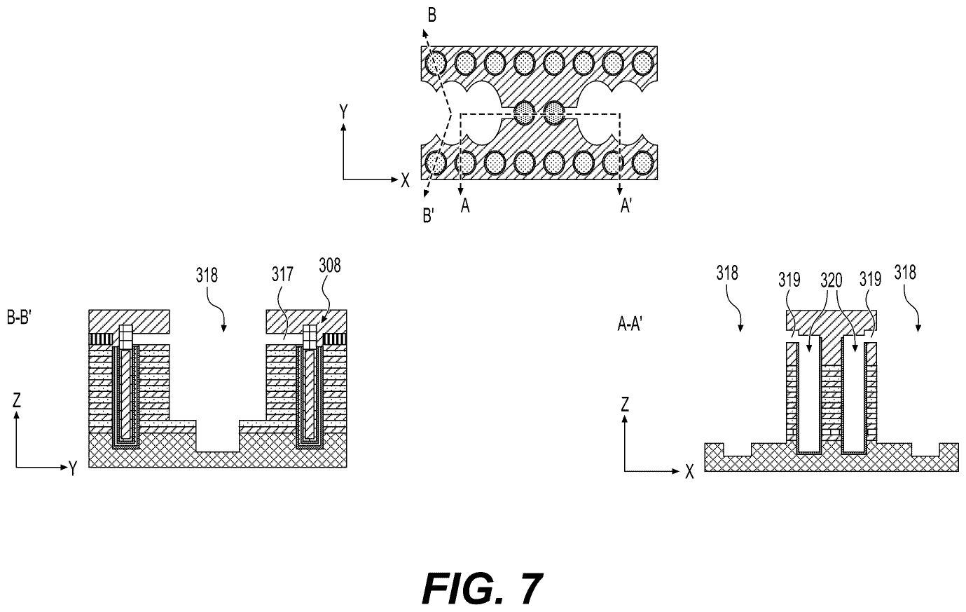

As shown in FIG. 6, an etch process can be performed to form gate line holes 318. The etch process removes material within the GLS hole structures 310A and enlarges the GLS hole structures 310A in the x-direction and y-direction. The GLS hole structures 310A are merged with its neighboring GLS hole structures 310A to form gate line slits 322. Since the doped region 314 in the topmost dielectric layer 304T has been doped during an implantation process, the etch rate of the doped region 314 would be faster than the etch rate within the GLS hole structures 310A in the lateral direction (x direction and y direction). This would result in portion of the doped region 314 surrounds the channel structures 308 and the second sequence of the GLS hole structures 310B being removed to create a cavity 317 and cavity 319. In the y direction, the etchant may reach the doped plug structures 312 and remove portion therein, which would damage the plug structure 312 and affect the performance of the memory cells below the plug structure 312. In the x direction, the cavity 319 may reach the top of the GLS hole structure 310B. In some cases, the etchant may remove all or a portion of the filling material of the GLS hole structures 310B, resulting in a cavity 320 in the GLS hole structures 310B, as shown in AA′ cross section view of FIG. 7. A material used to fill the cavity 319 may enter the cavity 320 and block an etchant entering the GLS hole structure 310 in a later stage of the fabrication process, causing an etch process for enlarging the GLS hole structure 310B to fail.

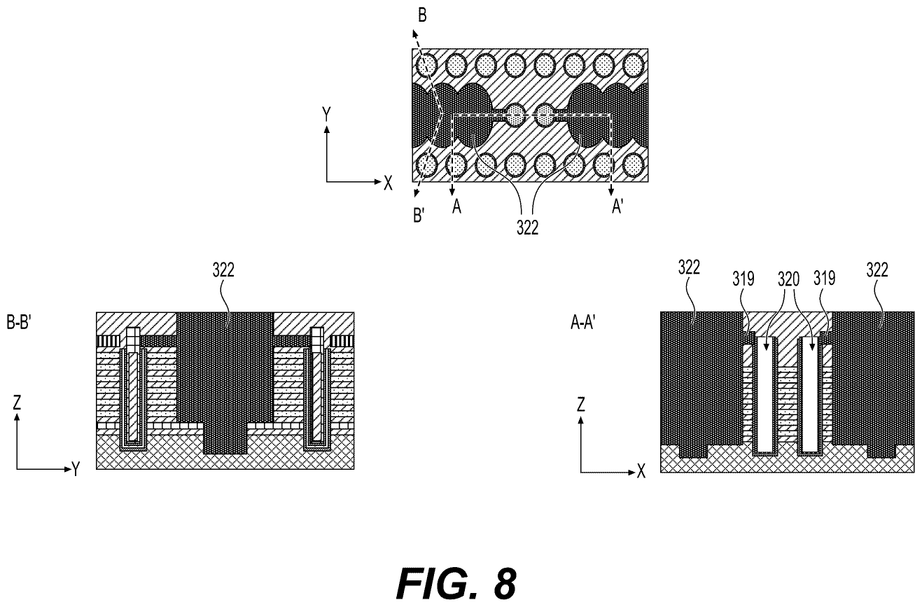

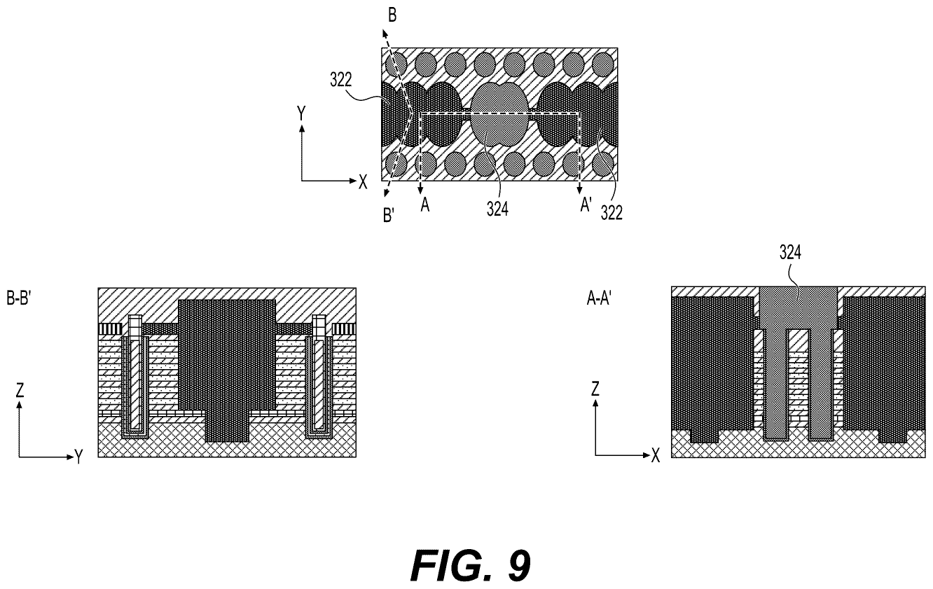

In FIG. 7, an oxidation process is performed to oxidize the internal surface of the gate line holes 318 (or the gate line slits 322). In the case that the cavity 320 was formed in the earlier step, the internal surface of the cavity 320 would also be oxidized. In FIG. 8, the gate line slits 322 are filled with a sacrificial material. Due to the existence of the cavity 320, the sacrificial material may be deposited on sidewalls of the cavity 320 through the cavity 319. The sacrificial material deposited on sidewalls of the cavity 320 may restrict an enlarge and merge process of the GLS hole structures 310B in a later stage of the fabrication process. In FIG. 9, a dielectric layer above the second sequence of the GLS hole structures 310B are etched away to expose the GLS hole structures 310B. A filling material can be removed from the GLS hole structures 310B to empty the GLS hole structures 310B. An etch process for enlarging the GLS hole structures 310B can be performed. The enlarged GLS hole structures 310B are supposed to merge with its neighboring GLS hole structures 310B as well as the neighboring gate line slits 322, resulting in a separation structure 324 merged with the gate line slits 322. However, the existing sacrificial material (used for filling the gate line slits 322) above the GLS hole structures 310B may block the etchant entering the GLS hole structures 310B. Further, existing sacrificial material on the sidewalls of the cavity 320 may restrict the etchant to enlarge the GLS hole structures 310B. As a result, the GLS hole structures 310B are not enlarged in the lateral direction and not merged with neighboring GLS hole structures 310B.

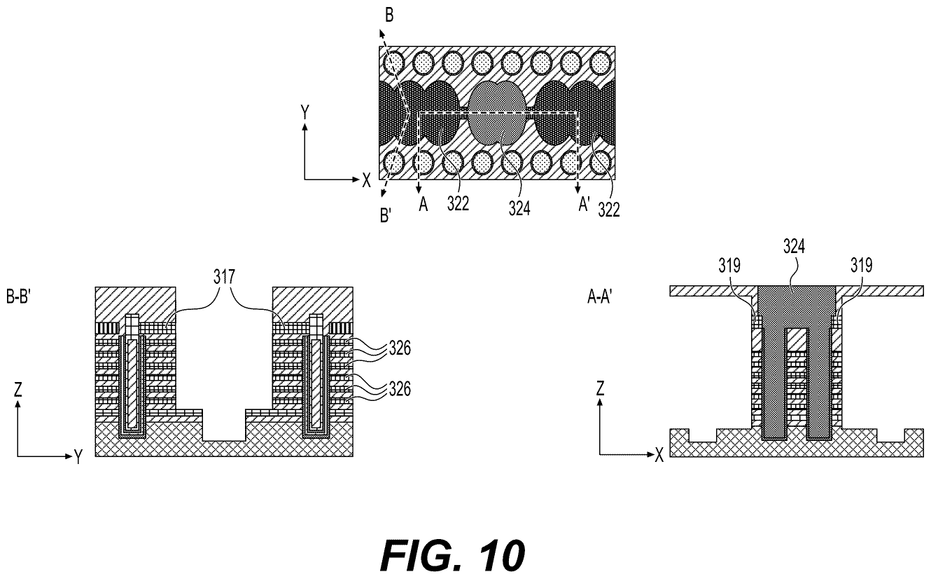

As shown in FIG. 10, the sacrificial material within the gate line slits 322 can be removed by performing an etch process. Then, the sacrificial layer 306 are replaced with word lines 326. The cavity 317 would also be filled with word line material, such as conductive material like polysilicon, metals, metal compounds, or silicides. This would create electrical connection between neighboring plug structures of the channel structures, which would make the memory device inoperable.

Further, as shown in the cross-section along the AA′ cut line of FIG. 10, conductive material would also reach into the separation structure 324 via the cavity 319. This could lead potential electrical connection between neighboring array regions that are supposed to be separated by gate line structures (formed from gate line slits 322 in a later process) and the separation structure 324. Furthermore, because the GLS hole structures 310B are not enlarged laterally, the conductive material of the word lines 326 may exist at regions surrounding the GLS hole structures 310B, shortening neighboring array regions. Therefore, the present disclosure is introduced to overcome the above-mentioned deficiencies of the conventional fabrication process.

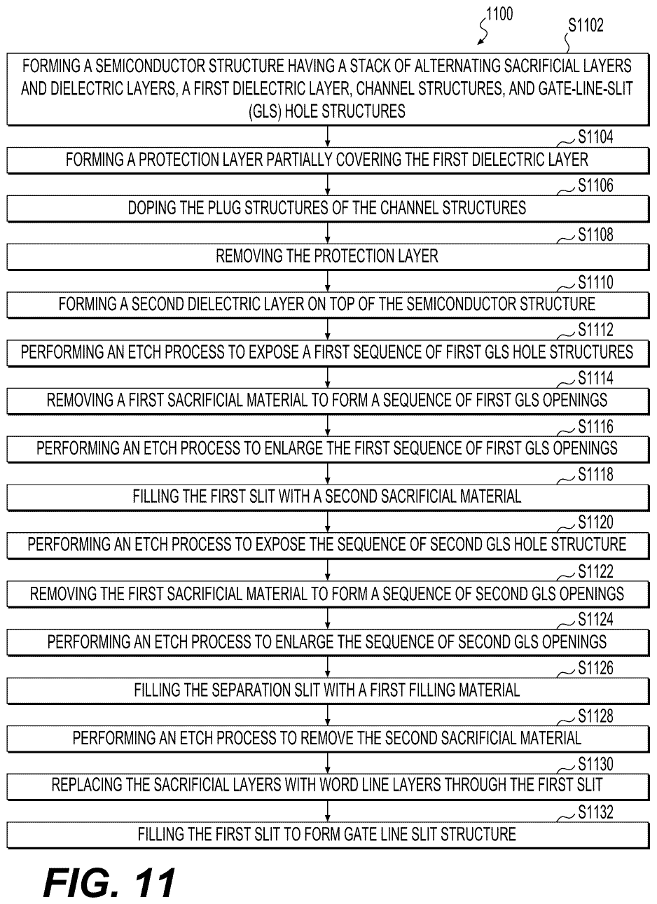

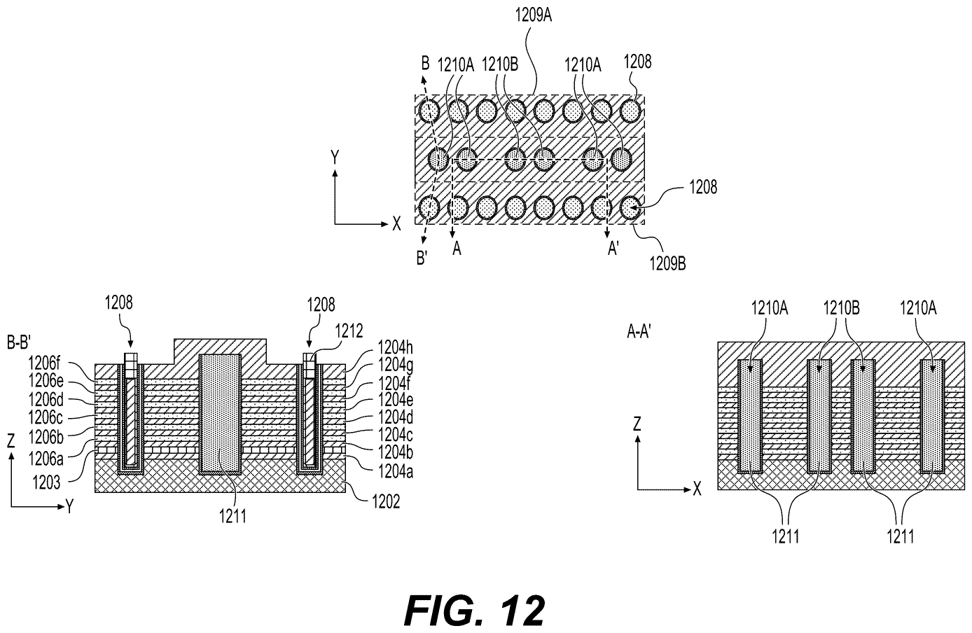

FIG. 11 illustrates a flowchart of a fabrication process 1100 of forming a semiconductor device 1200 according to aspects of the present disclosure. FIGS. 12-25 illustrate a sequence of semiconductor structures corresponding to different stages of the fabrication process 1100 according to aspects of the present disclosure. Each of the FIGS. 12-25 shows a top view and two cross-sections of the semiconductor device 1200. FIGS. 12-25 and process 1100 in FIG. 11 will be discussed together below. It is understood that the steps shown in process 1100 are not exhaustive and other steps may be performed as well before, after, or between any of the illustrated operations. Further, some of the steps may be performed simultaneously, or in a different order than shown in FIGS. 12-25 and FIG. 11. The process 1100 can start at S1101 and proceed to S1102.

At S1102, as shown in FIG. 12, a stack structure including a plurality of dielectric layers 1204a-1204h and the plurality of sacrificial layers 1206a-1206f is formed on substrate 1202. Dielectric layers 1204a-1204h and sacrificial layers 1206a-1206f are alternatingly arranged on substrate 1202. Dielectric layers 1204a-1204h and sacrificial layers 1206a-1206f can extend along the x-direction and the y-direction. Dielectric layers 1204a-1204h and sacrificial layers 1206a-1206f can be formed by one or more thin film deposition processes including, but not limited to, chemical vapor deposition (CVD), physical vapor deposition (PVD), atomic layer deposition (ALD), or any combination thereof. Dielectric layers 1204a-1204h can include dielectric materials, including, but not limited to, silicon oxide, silicon nitride, silicon oxynitride, or any combination thereof. In some implementations, an etch stop layer 1203 can be formed between the dielectric layer 1204a and dielectric layer 1204b. The etch stop layer 1203 can be used to provide layer protections during later processes.

Channel structures 1208 and gate-line-slit (GLS) hole structures 1210A/1210B are formed in the stack structure along the z-direction. The channel structures 1208 can be formed in array regions 1209 (e.g., 1209A and 1209B). A first sequence of GLS hole structures 1210A can have multiple GLS hole structures neighboring each other. A second sequence of GLS hole structures 1210B can have multiple GLS hole structures neighboring each other. The second sequence of GLS hole structures 1210B can be disposed in between GLS hole structures 1210A.

Each of the GLS hole structures (1210A or 1210B) can be filled with a first sacrificial material 1211 that can be removed in a later stage. The GLS hole structures 1210A/1210B can be formed in M&G between two array regions. For example, as shown in the top view, the GLS hole structures 1210A/1210B are formed between the array region 1209A and array region 1209B. The channel structures 1208 each can have a plug structure 1212 at an end of the respective channel structure 1208. As shown in the cross-section view along the BB′ cut line, the plug structures 1212 are exposed while the GLS hole structures 1210A/1210B are covered by the topmost dielectric layer 1204h.

In some implementations, each channel structure 1208 may include a semiconductor channel and a memory film formed over the semiconductor channel. In some implementations, a channel hole is formed in the stack structure along the z-direction. An etch process may be performed to form the channel hole through the interleaved dielectric layers 1204 and sacrificial layers 1206. Fabrication processes for forming the channel hole may include wet etching and/or dry etching, such as deep reactive ion etching (DRIE). In some implementations, the channel hole may extend further into substrate 1202. Then, a blocking layer, a storage layer, a tunneling layer, and a semiconductor channel may be sequentially formed in the channel hole. A plug structure 1212 can then be formed in the top portion of the channel hole.

As shown in the cross-section views along the AA′ cut line and the BB′ cut line, the topmost dielectric layer 1204h covers the GLS hole structures 1210A/1210B and the plug structures 1212 are exposed.

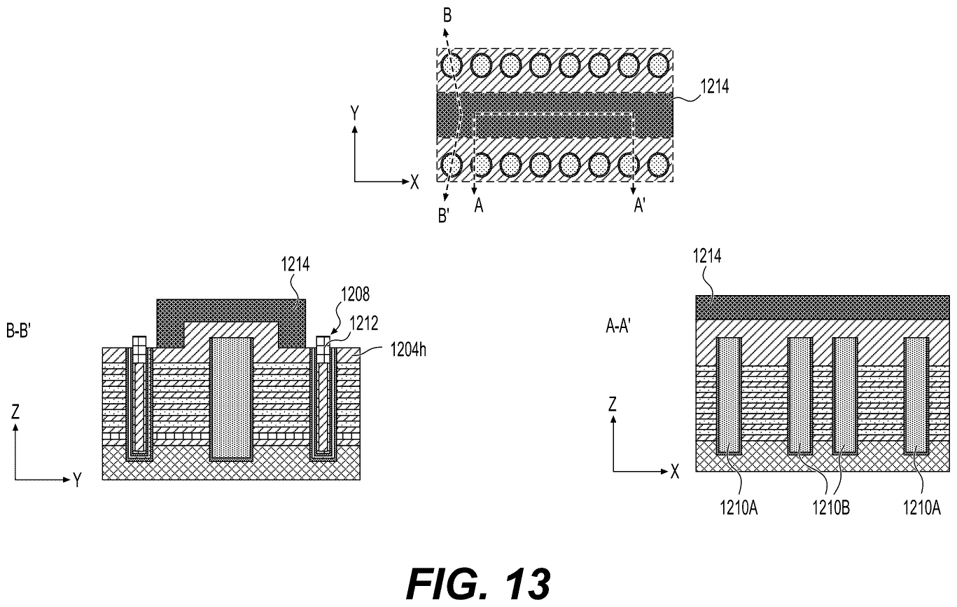

At S1104, as shown in FIG. 13, a protection layer 1214 (e.g., photoresist layer) can be disposed on the stack structure. The protection layer 1214 partially covers the topmost dielectric layer 1204h. The protection layer 1214 is positioned over the row of the GLS hole structures 1210A/1210B. As shown in the cross-section views along the BB′ cut line, in the lateral direction, the protection layer 1214 is disposed adjacent to the channel structures 1208 but does not cover the channel structure 1208 and the plug structures 1212. In some implementations, the protection layer 1214 can be any types of material that can prevent dopants from entering the dielectric layers below to change the characteristics of the dielectric layers. The protection layer needs to protect the dielectric layers below from being damaged by a doping process, such as ion implantation. In an implementation, the protection layer 1214 is formed in a way that the edge of the protection layer 1214 in the y direction is as close to the channel structures 1208 as possible. In an implementation, the edge of the protection layer 1214 in the y direction is positioned at a certain distance away from the channel structures 1208.

The process of forming the protection layer 1214 can include applying a photoresist layer onto the topmost dielectric layer 1204h. A mask (photo mask) containing a predefined pattern of opaque and transparent regions can be applied to the photoresist layer. Depending on selection of the photoresist material of the photoresist layer, an opaque region of the mask can cover the row of the GLS hole structures or can cover the channel structures. For example, when a positive photoresist material is used, the mask can be patterned such that an opaque region covers the row of GLS hole structures. For another example, when a negative photoresist material is used, the mask can be patterned such that an opaque region covers the channel structures. The edge of the opaque region can be controlled to be as close to the channel structures as possible. The semiconductor device 1200 can then be exposed to UV light to have the mask pattern transferred onto the photoresist layer. After exposure, a developer solution is applied to form the protection layer. For example, with a positive photoresist material, the developer solution removes the photoresist material that was not covered by the opaque region. For example, with a negative photoresist material, the developer solution removes the photoresist material that was covered by the opaque region. Therefore, the protection layer 1214 covering the row of the GLS hole structures 1210A/1210B can be formed.

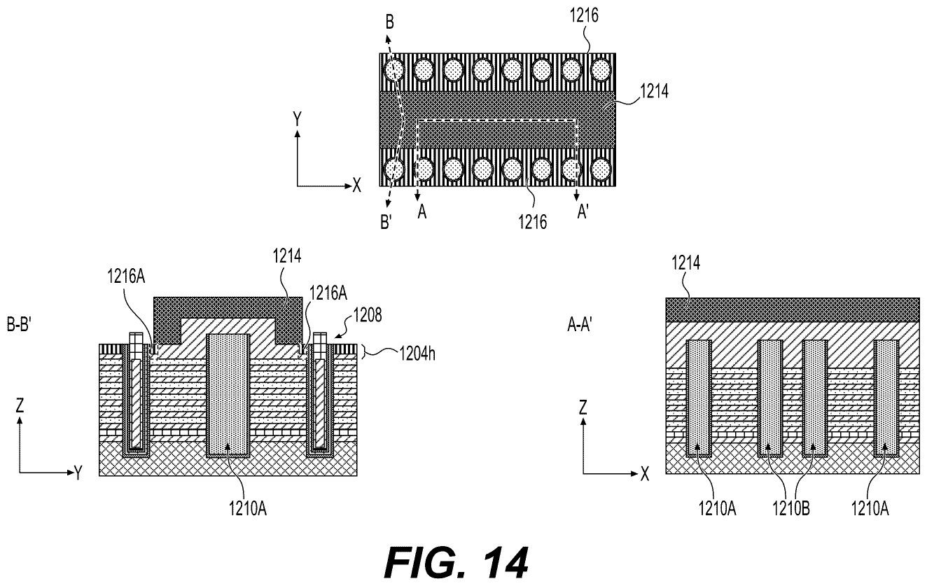

At S1106, as shown in FIG. 14, a doping process can be performed to the plug structure 1212 to increase its conductivity. During the doping process, the topmost dielectric layer 1204h is also doped, resulting in doped regions 1216 at two sides of the protection layer 1214. For example, an ion implantation (IMP) process may be performed to dope the plug structure 1212 with p-type dopants (e.g., boron, indium, gallium, etc.), or n-type dopants (e.g., phosphorus, arsenic, etc.), to a desired doping concentration. For p-type in-situ doping, p-type doping precursors, such as, but not limited to, diborane (B2H6) and boron trifluoride (BF3), can be used. For n-type in-situ doping, n-type doping precursors, such as, but not limited to, PH3 and AsH3, can be used. In some implementations, after the IMP process, an array thermal treatment can be applied to active dopants in doped plug structure 1212. When the protection layer 1214 was positioned as close to the channel structures 1208 as possible, a doped region 1216A of the topmost dielectric layer 1204h between the GLS hole structures 1210A/1210B and the channel structures 1208 is kept minimum.

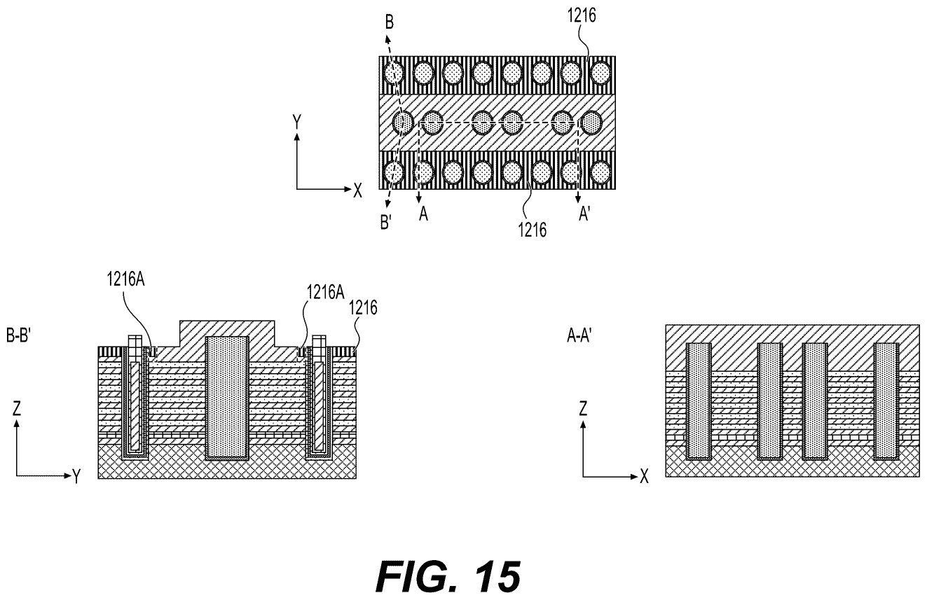

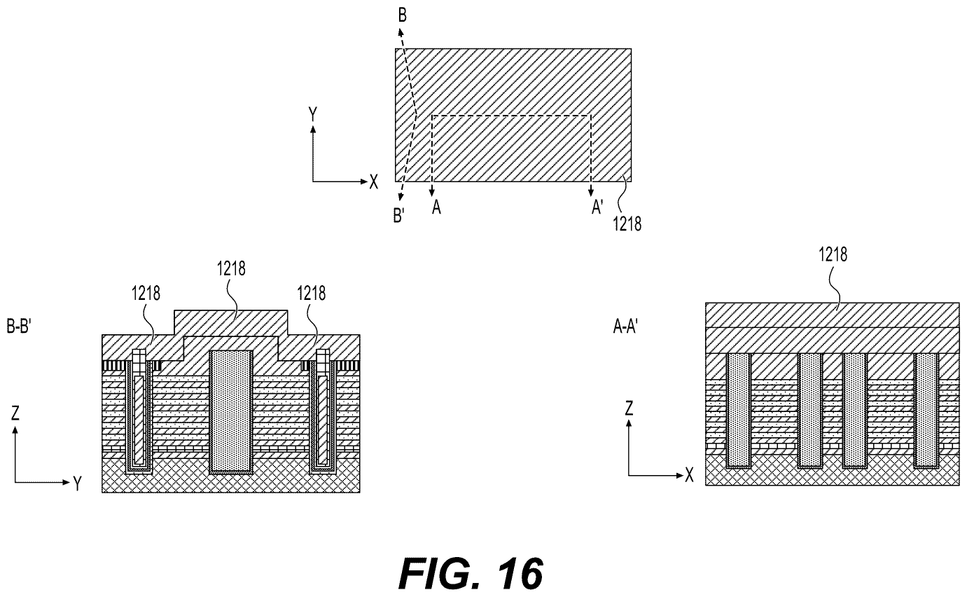

At S1108, as shown in FIG. 15, the protection layer 1214 is removed. For example, a plasma ashing and a wet clean can be applied to remove the protection layer 1214 in an implementation. At S1110, as shown in FIG. 16, a dielectric layer 1218 can be formed on the top of the semiconductor structure 1200. The dielectric layer 1218 can be formed by one or more thin film deposition processes, such as ALD, CVD, PVD, any other suitable processes, or any combination thereof. The dielectric layer 1218 can include dielectric materials, including, but not limited to, silicon oxide, silicon nitride, silicon oxynitride, or any combination thereof. The dielectric layer 1218 can be the same material as the dielectric layer 1204. The dielectric layer 1218 can be a different material than the dielectric layer 1204.

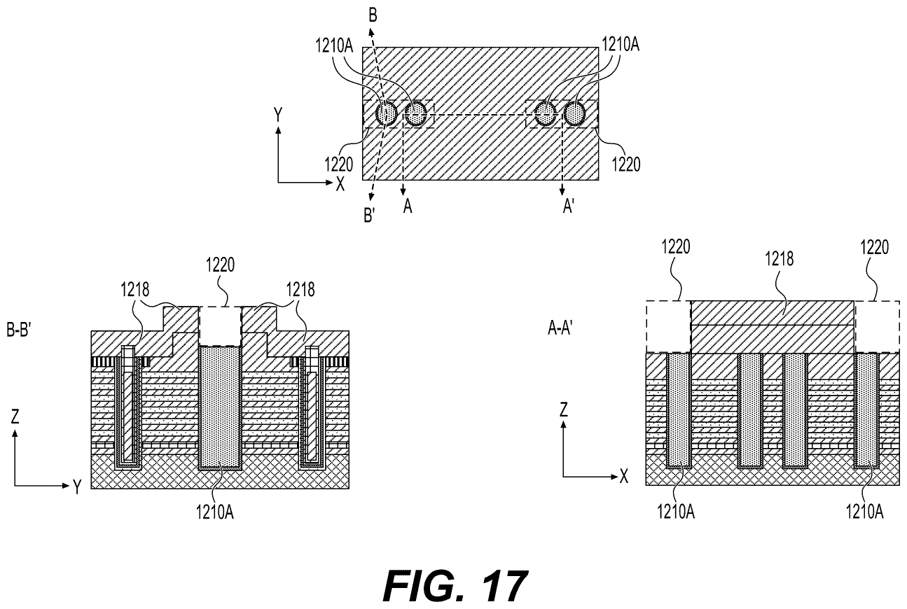

At S1112, as shown in FIG. 17, a trench 1220 can be formed on the stack structure to expose the first sequence of GLS hole structures 1210A. A photoresist layer (not shown) can be formed over the dielectric layer 1218 and patterned. A mask can be used to pattern the photoresist layer. A UV light can be used to transfer the pattern of the mask onto the photoresist layer. An etch process can be subsequently performed to expose the first sequence of GLS hole structures 1210A.

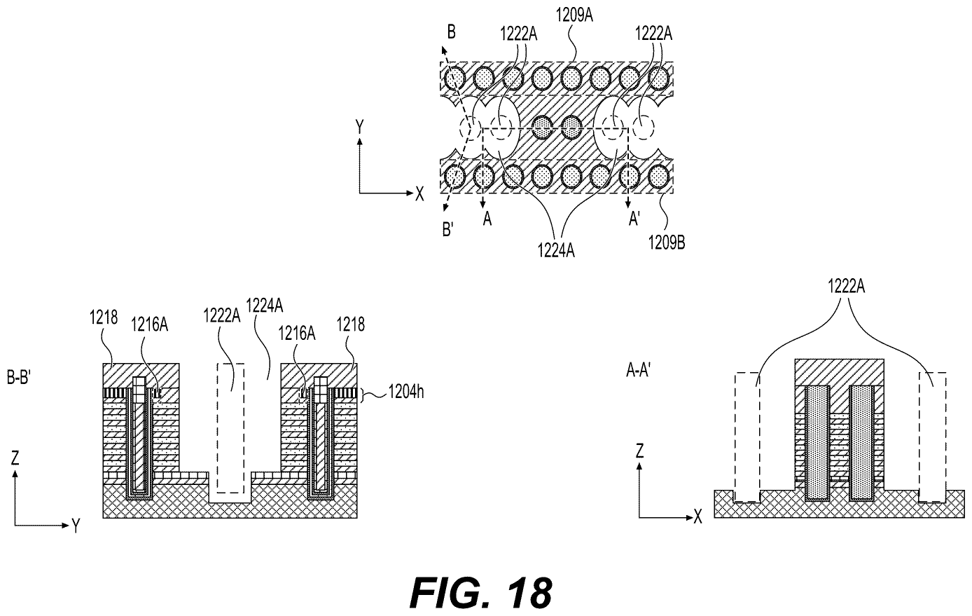

At S1114, as shown in FIG. 18, the first sacrificial material 1211 can be removed from the first sequence of GLS hole structures 1210A to form a sequence of first GLS openings 1222A. In some implementations, the first sacrificial material 1211 can be a polysilicon layer or a silicon nitride layer and can be removed by wet etch, dry etch, or other suitable processes. At S1116, the sequence of first GLS openings 1222A can be enlarged by performing an etch process. The sequence of first GLS openings 1222A can be enlarged in x-direction and y-direction. As shown in the top view of FIG. 18, by enlarging the first GLS openings 1222A in x-direction, the first GLS openings 1222A merge with its neighboring first GLS openings 1222A to form a first slit 1224A. A wavy boundary between the first slit 1224A and the array region 1209A or the array region 1209B can be formed as a result of the etch process.

Since the doped region 1216A of the topmost dielectric layer 1204h between the GLS hole structures 1210A/1210B and the channel structures 1208 is kept to a minimum in S1106, the process window of the etch process to enlarge the sequence of first GLS openings 1222A can be widened. For example, the etch process should be carefully controlled to avoid etching through the doped region 1216A and damaging the adjacent channel structures 1208. Because of the presence of undoped regions between the fist GLS openings 1222A and the doped region 1216A, the control parameters of the etch process, such as etch time, chamber pressure and temperature, etc. can be adjusted with more flexibility, which reduces the fabrication cost. In addition, because of the protection of undoped regions, the design of the semiconductor device 300 can adopt a smaller feature size to increase memory cell density.

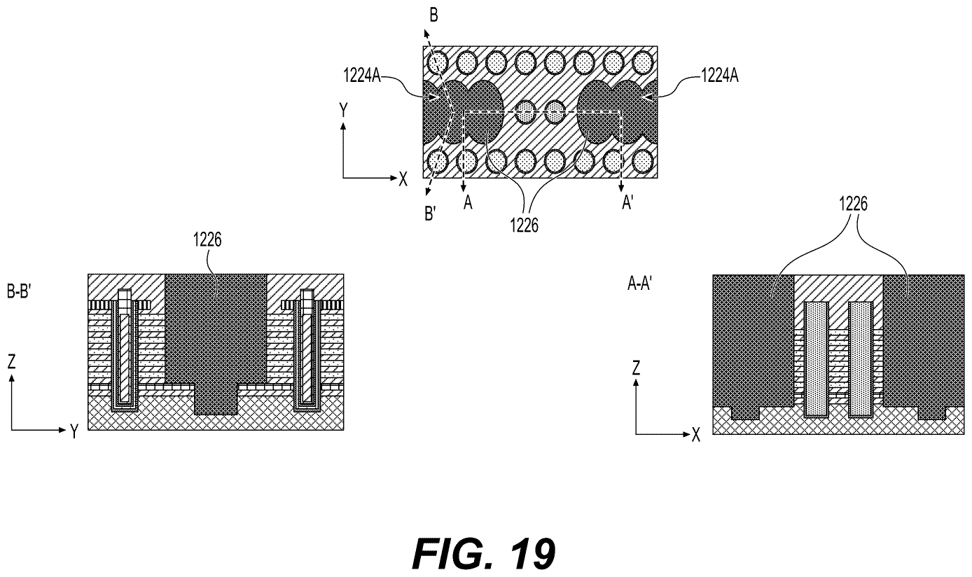

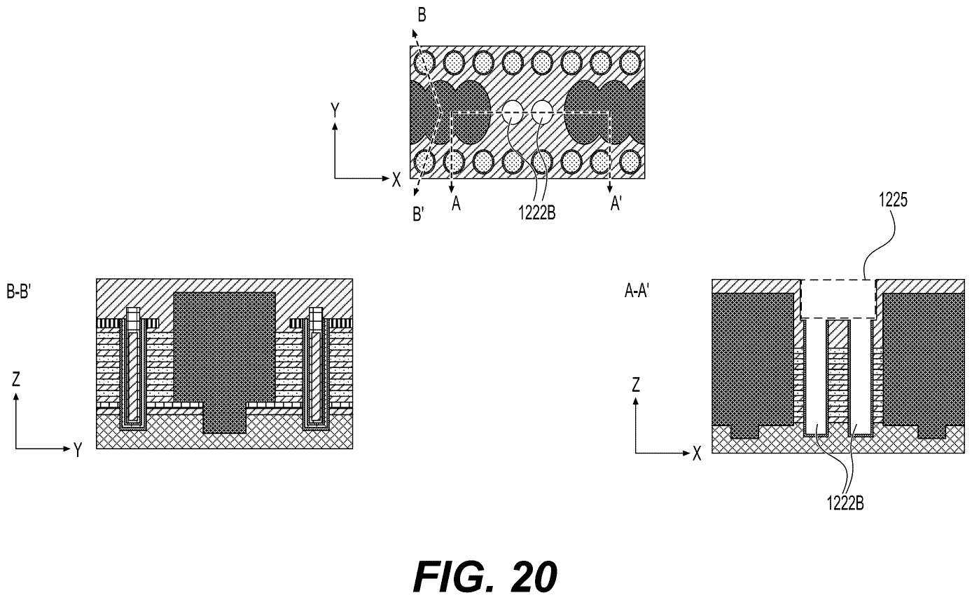

At S1118, as shown in FIG. 19, the first slit 1224A can be filled with a second sacrificial material 1226 that can be removed in a later process. At S1120, as shown in FIG. 20, a trench 1255 can be formed above the second sequence of GLS hole structures 1210B. A similar process as S1112 can be performed to expose the second sequence of GLS hole structures 1210B. A mask that selectively exposes the second sequence of GLS hole structures can be used to pattern a photoresist layer. An etch process can be subsequently performed to expose the second sequence of GLS hole structures 1210B. At S1122, as shown in FIG. 20, the first sacrificial material 1211 within the second sequence of GLS hole structures 1210B can then be removed to form a sequence of second GLS openings 1222B. In some implementations, the first sacrificial material 1211 can be a polysilicon layer or a silicon nitride layer and can be removed by wet etch, dry etch, or other suitable processes.

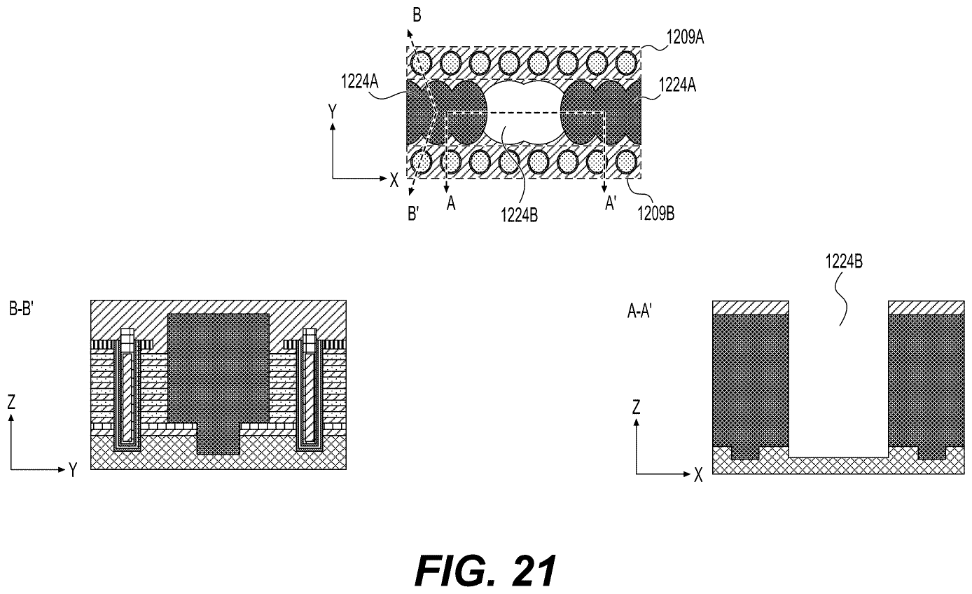

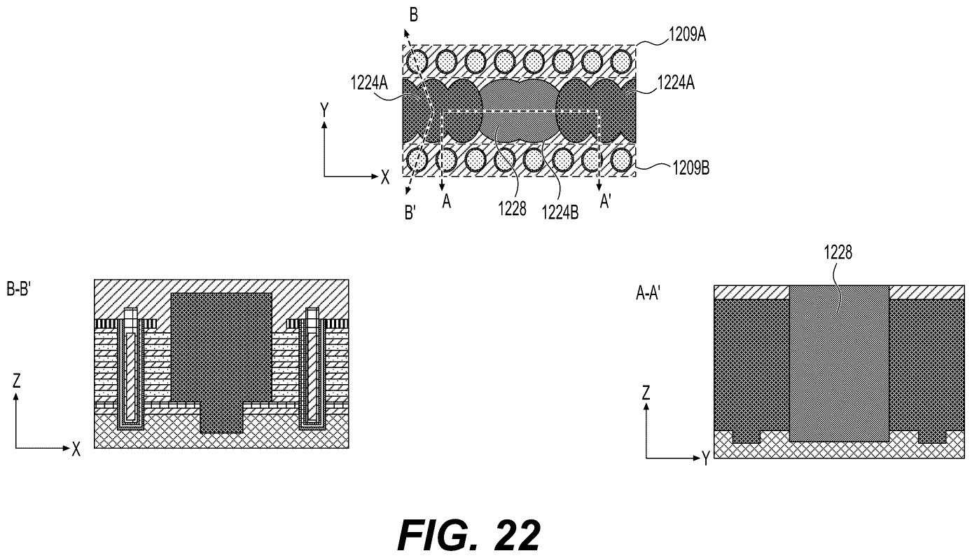

At S1124, as shown in FIG. 21, the sequence of second GLS openings 1222B can be enlarged by performing an etch process. The sequence of second GLS openings 1222B can be enlarged in x-direction and y-direction. As shown in the top view of FIG. 21, by enlarging the second GLS openings 1222B in x-direction, the second GLS openings 1222B merge with its neighboring second GLS openings 1222B to form a second slit 1224B (i.e., a separation slit). A wavy boundary between the second slit 1224B and the array region 1209A or the array region 1209B can be formed as a result of the etch process. Also, the second slit 1224B shares sidewalls with the first slit 1224A in the x-direction. At S1126, as shown in FIG. 22, a separation structure 1228 can be formed by filling the second slit 1224B with a first filling material. For example, the second slit 1224B can be filled with an insulating material, such as silicon dioxide, silicon nitride, or high-k dielectrics. The first slit 1224A and the separation structure 1228 are connected with each other. As shown in the top view of FIG. 22, the array region 1209A and the array region 1209B are separated and isolated by the first slit 1224A and the separation structure 1228.

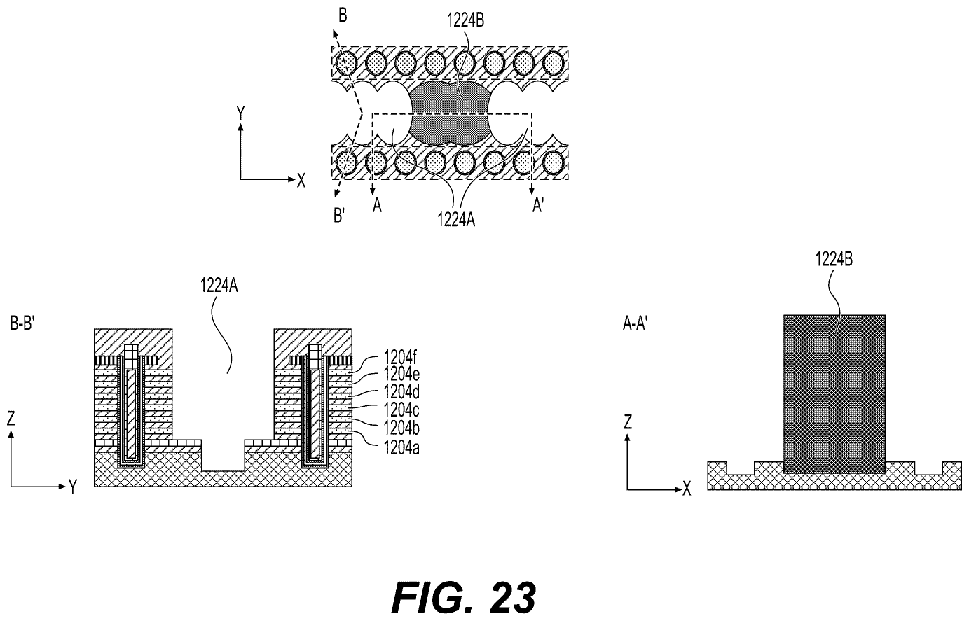

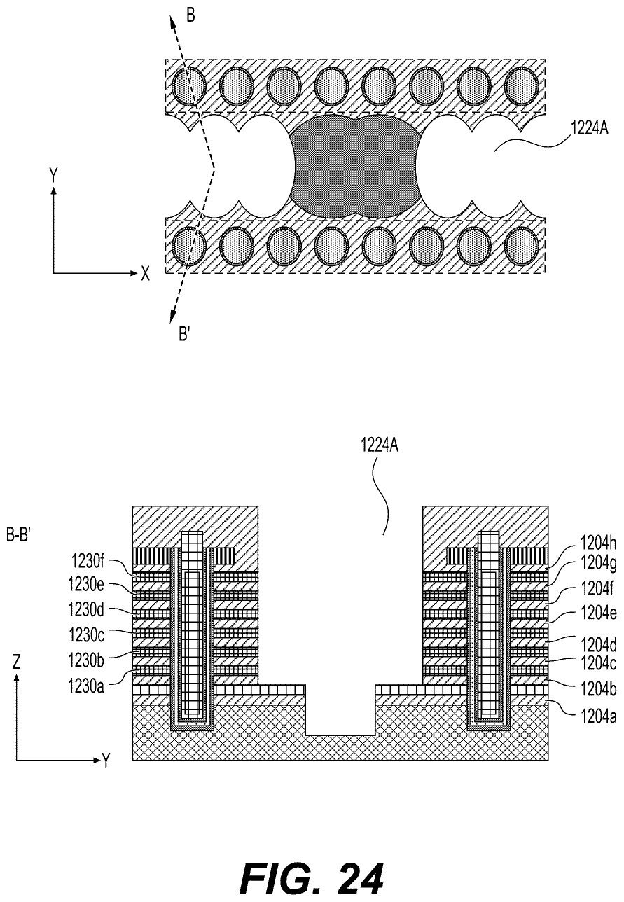

At S1128, as shown in FIG. 23, the second sacrificial material 1226 can be removed from the first slit 1224A. In some implementations, the second sacrificial material 1226 can be removed by wet etch, dry etch, or other suitable processes. At S1130, as shown in FIG. 24, the sacrificial layers 1206a-1206f can be replaced with word line layers 1230a-1230f. In some implementations, a plurality of cavities may be first formed by removing the sacrificial layers 1206a-1206f through the first slit 1224A. In some implementations, sacrificial layers 1206a-1206f are removed by applying etchants through the first slit 1224A, creating cavities interleaved between the dielectric layers 1204a-1204h. The etchants can include any suitable etchants that selective etch the sacrificial layers 1206a-1206f.

Then, the word line layers 1230a-1230f are deposited into the cavities through the first slit 1224A. In some implementations, the word line layers 1230a-1230f can be formed by thin film deposition, thermal growth, and any other suitable processes. In some implementations, the word line layers 1230a-1230f can include any suitable conductive materials, such as polysilicon, metals (e.g., W, Cu, Al, etc.), metal compounds (e.g., TiN, TaN, etc.), or silicides. For example, the word line layers 1230a-1230f can include doped polysilicon, i.e., a gate poly. In some implementations, the word line layers 1230a-1230f can include multiple conductive layers, such as a W layer over a TiN layer. In some implementations, a removal process may be performed to clean the first slit 1224A. The removal process may remove the residues of previous procedures of the first slit 1224A.

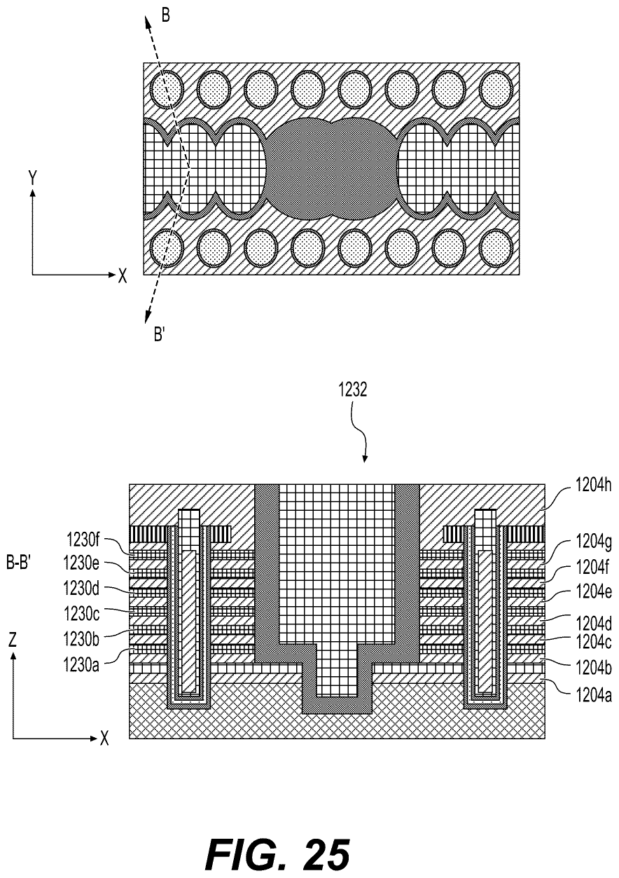

At S1132, as shown in FIG. 25, the first slit 1224A can be filled to form a gate line slit structure 1232. The gate line slit structure 1232 can extend vertically along the z-direction through the stack structure and can also extend laterally along the x-direction to separate the array regions 1209A/1209B. In some implementations, the gate line slit structure 1232 may be filled by using CVD, PVD, ALD, or other suitable processes. In some implementations, the gate line slit structure 1232 may include a gate line contact, formed by filling the first slit 1224A with conductive materials including, but not limited to, W, Co, Cu, Al, polysilicon, silicides, or any combination thereof. The gate line slit structure 1232 may further include a composite spacer disposed laterally between the slit contact and word line layers 1230a-1230f and dielectric layers 1204a-1204h to electrically insulate the gate line slit structure 1232 from surrounding the word line layers in the stack structure. In some implementations, the gate line slit structure 1232 may include dielectric materials when the slit contact is not required in the semiconductor device 1200. As shown in the top view of FIG. 25, a wavy boundary between the gate line slit structure 1232 and the array region 1209A or the array region 1209B can be formed as a result of the etch process. The dopant concentration of the topmost dielectric layer 1204h has a transition at the wavy boundary from a higher concentration to a lower concentration. The process 1100 can then proceed to S1199 and terminates at S1199.

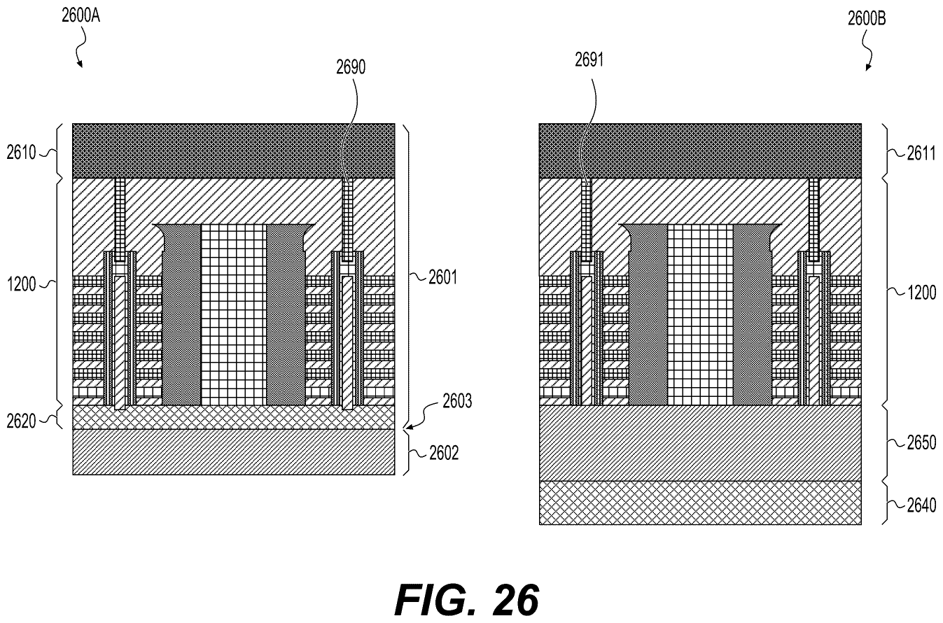

FIG. 26 shows two semiconductor memory device architectures 2600A and 2600B where the fabrication methods disclosed herein are applied according to some implementations of the present disclosure. The architecture 2600A in FIG. 26 can be a stacked structure where two wafers 2601 and 2602 are bonded together via a bonding interface 2603. To form the structures in the upper wafer 2601, additional fabrication processes can be performed after the forming of the semiconductor device 1200. For example, the semiconductor device 1200 can be thinned from its backside to expose the back end of the channel structures. The oxide-nitride-oxide layer of the channel structure can then be removed to expose the channel layer inside. Later, a backside layer 2620 can be formed on the backside of the semiconductor device 1200. The backside layer 2620 can function as a common source layer to connect the channel layer of the channel structure. A back-end-of-line (BEOL) layer 2610 can be formed over the semiconductor device 1200. As an example, contact structures 2690 are shown to connect plug structures of channel structures with the BEOL layer 2610. The wafer 2602 can include peripheral circuits for controlling the operations of the semiconductor structure 1200. In an implementation, the peripheral circuits are formed with complementary metal-oxide-semiconductor (CMOS) technology. The two wafers 2601 and 2602, after being formed separately, can be bonded together at the bonding interface 2603.

The architecture 2600B can be formed over a same substrate 2640. For example, a CMOS peripheral circuits layer 2650 can first be formed over the substrate 2640. The structure of the semiconductor device 1200 can then be formed over the CMOS peripheral circuits layer 2650. A BEOL layer 2611 can be formed over the semiconductor device 1200. Similarly, contact structures 2691 are shown to connect plug structures of channel structures with the BEOL layer 2611.

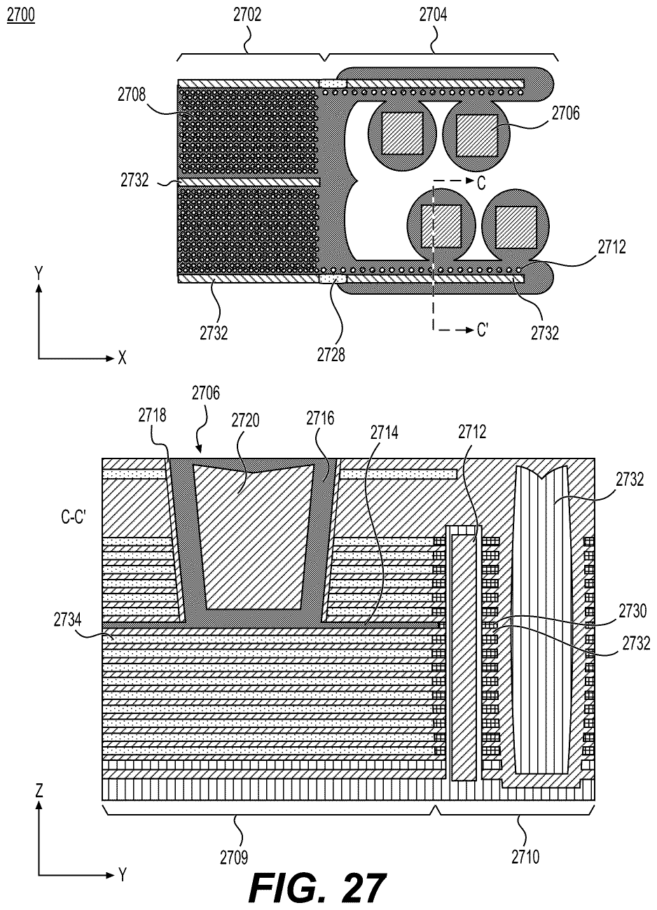

FIG. 27 illustrates a top view and a cross-section view of a block 2700 of a semiconductor device having word line connecting structures 2706 according to some aspects of the present disclosure. The block 2700 has a core array region 2702 and a word line connecting region 2704. The core array region 2702 includes an array of channel structures 2708. The word line connecting region 2704 includes multiple word line connecting structures 2706 and dummy channel structures 2712. The fabrication methods disclosed herein are employed to form the core array region 2702 and the word line connecting region 2704, as well as gate line slit structure 2732 and separation structure 2728. gate line slit structures 2732 and separation structures 2728 separate neighboring blocks of the semiconductor device.

As shown in the cross-section view along the CC′ cut line of the block 2700, the word line connecting region 2704 can include a dielectric portion 2709 and a conductive portion 2710.

The conductive portion 2710 can include a dummy channel structure 2712 and gate line slit structures 2732. The dummy channel structure 2712 and gate line slit structures 2732 extend vertically through interleaved conductive layers 2730 and dielectric layers 2732. The word line connecting structure 2706 extends through interleaved dielectric layers 2732 and dielectric layers 2734 in the dielectric portion 2709.

Each word line connecting structure 2706 connects with a corresponding conductive layer 2730 via interconnect line 2714 of each word line connecting structure 2706. The interconnect line 2714 can extend laterally in the y-direction to be in contact with the corresponding conductive layer 2730 at the same level of the stack. The word line connecting structure 2706 can further include a vertical contact 2716, a contact spacer 2718 circumscribing vertical contact 2716. The vertical contact 2716 connects with the interconnect line 2714. Vertical contact 2716 and interconnect line 2714 can include conductive materials including, but not limited to, W, Co, Cu, Al, TiN, polysilicon, doped silicon, silicides, or any combination thereof. Contact spacer 2718 can include dielectric materials including, but not limited to, silicon oxide, silicon nitride, silicon oxynitride, or any combination thereof. In some implementations, vertical contact 2716 and interconnect line 2714 include TiN/W, and contact spacer 2718 includes silicon oxide.

In some implementations, word line connecting structure 2706 further includes a filler 2720 circumscribed by vertical contact 2716. That is, the word line connecting opening may not be fully filled with contact spacer 2718 and vertical contact 2716, and the remaining space of the word line connecting opening may be filled with dielectric materials, including, but not limited to, silicon oxide, silicon nitride, silicon oxynitride, or any combination thereof, as filler 2720.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A three-dimensional (3D) memory device, comprising:
a first stack of alternating conductive layers and dielectric layers;
a first dielectric layer that is formed over the first stack;
a first slit structure extending through the first stack and the first dielectric layer, the first slit structure being disposed adjacent to an array region; and
channel structures that are formed in the array region and extend through the first stack and the first dielectric layer,
wherein the first dielectric layer in the array region includes a first portion and a second portion, the first portion being closer to the first slit structure than the second portion, and the second portion having a higher dopant concentration than the first portion.

2. The device of claim 1, further comprising a second slit structure and a separation structure that extend through the first stack and the first dielectric layer, the separation structure being disposed between the first slit structure and the second slit structure.

3. The device of claim 1, wherein the first portion and the second portion of the first dielectric layer are separated by a boundary within the first dielectric layer, dopant concentration of the first dielectric layer having a transition at the boundary from a higher concentration to a lower concentration.

4. The device of claim 3, wherein the boundary in the first dielectric layer extends substantially in parallel to an extending direction of the first slit structure.

5. The device of claim 1, wherein the channel structures each have a plug structure crossing the first dielectric layer, and the plug structures and the first dielectric layer in the second portion include a same type of doping element.

6. The device of claim 1, wherein, in a section crossing the first slit structure, a border between the first slit structure and the array region has a wavy shape.

7. The device of claim 1, further comprising:
a second stack of dielectric layers, the second stack being adjacent to the first stack; and
a connecting structure partially extending through the second stack and connecting with one of the conductive layers.

8. A three-dimensional (3D) memory device, comprising:
a first stack of alternating conductive layers and dielectric layers;
a first dielectric layer that is formed over the first stack;
a first slit structure extending through the first stack and the first dielectric layer, the first slit structure being disposed adjacent to an array region; and
channel structures that are formed in the array region and extend through the first stack and the first dielectric layer,
wherein the first dielectric layer in the array region includes a first portion and a second portion, the first portion being closer to the first slit structure than the second portion, the first portion and the second portion of the first dielectric layer being separated by a boundary within the first dielectric layer, dopant concentration of the first dielectric layer having a transition at the boundary from a higher concentration to a lower concentration.

9. The device of claim 8, further comprising a second slit structure and a separation structure that extend through the first stack and the first dielectric layer, the separation structure being disposed between the first slit structure and the second slit structure.

10. The device of claim 8, wherein the second portion has a higher dopant concentration than the first portion.

11. The device of claim 8, wherein, in the first dielectric layer, the boundary extends substantially in parallel to an extending direction of the first slit structure.

12. The device of claim 8, wherein the channel structures each have a plug structure crossing the first dielectric layer, and the plug structures and the first dielectric layer in the second portion include a same type of doping element.

13. The device of claim 8, wherein, in a section crossing the first slit structure, a border between the first slit structure and the array region has a wavy shape.

14. The device of claim 8, further comprising:
a second stack of dielectric layers, the second stack being adjacent to the first stack; and
a connecting structure partially extending through the second stack and connecting with one of the conductive layers.

15. A method for fabricating a three-dimensional (3D) memory device, comprising:
forming a semiconductor structure including:
a stack of alternating sacrificial layers and dielectric layers,
a first dielectric layer that is formed over the stack,
channel structures extending through the stack and the first dielectric layer, the channel structures each having a plug structure at an end of the respective channel structure, and
gate-line-slit (GLS) hole structures extending through the stack and into the first dielectric layer and arranged in a row;
forming a protection layer partially covering the first dielectric layer, wherein the protection layer is positioned over the row of the GLS hole structures and a region of the first dielectric layer where the channel structures are located remains exposed; and
doping the plug structures of the channel structures.

16. The method of claim 15, wherein the protection layer is a photo resist layer.

17. The method of claim 15, wherein the GLS hole structures include a first sequence of first GLS hole structures neighboring each other and a second sequence of second GLS hole structures neighboring each other in the row of the GLS hole structures, and the method further comprises:
removing the protection layer;
forming a second dielectric layer on top of the semiconductor structure covering the plug structures of the channel structures;
performing an etch process to expose the first sequence of first GLS hole structures from a top of the semiconductor structure;
removing a first sacrificial material from within the first sequence of first GLS hole structures to form a first sequence of first GLS openings extending through the stack and the first dielectric layer; and
performing an etch process to enlarge the first sequence of first GLS openings, wherein the enlarged sequence of first GLS openings merge with each other to form a first slit.

18. The method of claim 17, further comprising:
filling the first slit with a second sacrificial material;
performing an etch process to expose the sequence of second GLS hole structures from the top of the semiconductor structure;
removing the first sacrificial material from within the sequence of second GLS hole structures to form a sequence of second GLS openings extending through the stack and the first dielectric layer;
performing an etch process to enlarge the sequence of second GLS openings, wherein the enlarged sequence of second GLS openings merge with each other to form a separation slit; and
filling the separation slit with a first filling material.

19. The method of claim 18, wherein the first filling material is an insulation material.

20. The method of claim 18, further comprising:
performing an etch process to remove the second sacrificial material from the first slit;
replacing the sacrificial layers with word line layers through the first slit; and
filling the first slit with a second filling material.
